(19) United States
(12) Patent Application Publication
(10) Pub. No.: US 2018/0006257 A1
(43) Pub. Date: Jan. 4, 2018

(54) CARBON DOT MULTICOLOR PHOSPHORS

(71) Applicant: Weiyong YU, Shreveport, LA (US)

(72) Inventor: Weiyong YU, Shreveport, LA (US)

(73) Assignee: Board of Supervisors of Louisiana State University and Agricultural and Mechanical College, Baton Rouge, LA (US)

(21) Appl. No.: 15/640,433

(22) Filed: Jun. 30, 2017

Related U.S. Application Data
(60) Provisional application No. 62/356,720, filed on Jun. 30, 2016.

(51) Int. Cl. H01L 51/50; H01L 51/56; H01L 51/00; H05B 33/08; H01L 51/52

(52) U.S. Cl. CPC H01L 51/502; H05B 33/0857; H01L 51/5221; H01L 51/0026; H01L 51/0035; H01L 51/004; H01L 51/5056; H01L 51/56; H01L 51/0003; H01L 51/5206; H01L 51/5088; H01L 51/5072; H01L 2251/301; H01L 2251/306; H01L 2251/308; H01L 2251/5369; H01L 2251/558

(57) ABSTRACT

Carbon dots synthesized from p-phenylenediamine in diphenyl ether exhibit excitation wavelength independent long wavelength multicolor emissions (green to red) when they are dispersed in different solvents and polymers. The emissions are excitation wavelength independent and one excitation light can excite all the colors.

### CROSS REFERENCE TO RELATED APPLICATIONS/PRIORITY

The present invention claims priority to U.S. Provisional Patent Application No. 62/356,720, filed on Jun. 30, 2016, which is incorporated by reference into the present disclosure as if fully restated herein. Any conflict between the incorporated material and the specific teachings of this disclosure shall be resolved in favor of the latter. Likewise, any conflict between an art-understood definition of a word or phrase and a definition of the word or phrase as specifically taught in this disclosure shall be resolved in favor of the latter.

### FIELD OF THE INVENTION

One embodiment of the present invention relates to the field of fluorescent materials. A further embodiment of the presently claimed invention relates to photoluminescent nanomaterials as phosphors for color display and white lighting.

### BACKGROUND OF THE INVENTION

Carbon nanoparticles, also called carbon dots (CDs) have recently emerged as a new type of fluorescent material (comparing to traditional LED phosphors, rare earth fluorescent materials, small metal particles, semiconductor nanocrystals, organic dyes, fluorescent polymers, etc.) due to their multiple advantages, such as high photoluminescence quantum yield (QY), earth abundant raw materials, great environmental sustainability, low production cost, and excellent biocompatibility. CDs thus have been studied for broad applications including fluorescent probes and sensors, biolabeling and medical imaging, LED color display and lighting devices. In those applications, the fluorescence emission colors from blue to red are all needed, especially from green to red. Therefore, the development of preparing multicolor emission CD materials is highly desirable.

CDs can emit photoluminescence colors from blue to red, but most of them in currently practiced technology emit strong blue light, and the long wavelength lights (for example green, yellow, red) are obtained with long excitation wavelengths. Such excitation wavelength dependent emissions are generally ascribed to the different photon absorption mechanisms of the CDs and the QYs for yellow and red lights according to currently practiced technology are very low. Another way to obtain a long wavelength light is to use repeated photon absorption and emission with the extended light pathway length or the increased concentration of the CD particles in solutions or solid matrices—but, the emission efficiency using this method is very low, too.

### SUMMARY OF THE INVENTION

Wherefore, it is an object of the present invention to overcome the above mentioned shortcomings and drawbacks associated with the prior art.

The present invention relates to products and methods that according to one embodiment uses carbon nanoparticles (CDs) that can be nanosized crystalline or amorphous carbon particles, small graphene, short carbon nanotubes (single or multiple walls), with the CD have a size or width varying from, preferably 0.5 nm to 20 nm, and more preferably 2 nm to 10 nm, and most preferably between 2.3 nm and 4 nm, as the photoluminescent materials (phosphors) for various color emissions. The presently claimed invention preferably adjusts the media surrounding the CD particles for different color emissions. The media can be liquid or solid.

The present invention also relates to photoluminescent light-emitting diode (LED) device comprising a UV or blue LED chip and an emissive CD liquid or solid layer for color display and white-light lighting.

Various objects, features, aspects, and advantages of the present invention will become more apparent from the following detailed description of preferred embodiments of the invention, along with the accompanying drawings in which like numerals represent like components. The present invention may address one or more of the problems and deficiencies of the current technology discussed above. However, it is contemplated that the invention may prove useful in addressing other problems and deficiencies in a number of technical areas. Therefore the claimed invention should not necessarily be construed as limited to addressing any of the particular problems or deficiencies discussed herein

### BRIEF DESCRIPTION OF THE DRAWING

The patent or application file contains at least one drawing executed in color. Copies of this patent or patent application publication with color drawing(s) will be provided by the Office upon request and payment of the necessary fee.

The accompanying drawings, which are incorporated in and constitute a part of the specification, illustrate various embodiments of the invention and together with the general description of the invention given above and the detailed description of the drawings given below, serve to explain the principles of the invention. It is to be appreciated that the accompanying drawings are not necessarily to scale since the emphasis is instead placed on illustrating the principles of the invention. The invention will now be described, by way of example, with reference to the accompanying drawings in which:

FIG. 1 is a transmission electron microscope (TEM) image of CDs according to the presently invention.

FIG. 2 is the particles size distribution histogram of the CDs.

FIG. 3 is the high-resolution transmission electron microscope (HRTEM) image of the CDs.

FIG. 4 is the atomic force microscope (AFM) image of the CDs.

FIG. 5 is the Fourier transform infrared (FTIR) spectrum of the CDs.

FIG. 6 is the X-ray photoelectron spectroscopy (XPS) spectrum of the CDs.

FIG. 7 is the high-resolution XPS spectrum of C 1s of the CDs.

FIG. 8 is the high-resolution XPS spectrum of N 1s of the CDs.

FIG. 9 is the high-resolution XPS spectrum of O 1s of the CDs.

FIG. 10 shows the photoluminescence spectra of the CDs in 7 solvents excited by 420 nm light.

FIG. 11 shows the photoluminescence spectra of the CDs excited by different wavelength lights in CCl₄.

FIG. 12 shows the photoluminescence spectra of the CDs excited by different wavelength lights in toluene.

FIG. 13 shows the photoluminescence spectra of the CDs excited by different wavelength lights in CHCl₃.

FIG. 14 shows the photoluminescence spectra of the CDs excited by different wavelength lights in acetone.

FIG. 15 shows the photoluminescence spectra of the CDs excited by different wavelength lights in DMF.

FIG. 16 shows the photoluminescence spectra of the CDs excited by different wavelength lights in CH₃OH.

FIG. 17 shows the photoluminescence spectra of the CDs excited by different wavelength lights in H₂O.

FIG. 18 is the complete UV-vis absorption spectra (200-800 nm) of the CDs in the 7 solvents.

FIG. 19 is the amplified partial UV-vis absorption spectra (350-800 nm) of the same CDs in the 7 solvents.

FIG. 20 is the photoluminescence spectra (excited by 460 nm light) of the CDs methanol, ethanol, benzyl alcohol, 1-hexanol, and 1-octanol.

FIG. 21 is the fluorescence spectra of the CDs in ethanol under various excitation wavelengths.

FIG. 22 is the fluorescence spectra of the CDs in benzyl alcohol under various excitation wavelengths.

FIG. 23 is the fluorescence spectra of the CDs in 1-hexanol under various excitation wavelengths.

FIG. 24 is the fluorescence spectra of the CDs in 1-octanol under various excitation wavelengths.

FIG. 25 is the absorption spectra of the CDs in methanol, ethanol, benzyl alcohol, 1-hexanol, and 1-octanol.

FIG. 26 shows the photoluminescence spectra of five CD/polymer films excited at 420 nm (top) and the corresponding photos of excited five CD/polymer films (bottom).

FIG. 27 is the fluorescence spectra of CD/PS composite film under various excitation wavelengths.

FIG. 28 is the fluorescence spectra of CD/PMMA composite film under various excitation wavelengths.

FIG. 29 is the fluorescence spectra of CD/PVP composite film under various excitation wavelengths.

FIG. 30 is the fluorescence spectra of CD/PEG composite film under various excitation wavelengths.

FIG. 31 is the fluorescence spectra of CD/PVA composite film under various excitation wavelengths.

FIG. 32 shows the final formation of CD/polymer composite on a 370-nm UV LED chip (CD-LED).

FIG. 33 shows the bright green color emission from a CD-LED with CD/PMMA composite.

FIG. 34 shows the bright red color emission from a CD-LED with CD/PVA composite.

### DETAILED DESCRIPTION OF THE INVENTION

The present invention will be understood by reference to the following detailed description, which should be read in conjunction with the appended drawings. It is to be appreciated that the following detailed description of various embodiments is by way of example only and is not meant to limit, in any way, the scope of the present invention. In the summary above, in the following detailed description, in the claims below, and in the accompanying drawings, reference is made to particular features (including method steps) of the present invention. It is to be understood that the disclosure of the invention in this specification includes all possible combinations of such particular features, not just those explicitly described. For example, where a particular feature is disclosed in the context of a particular aspect or embodiment of the invention or a particular claim, that feature can also be used, to the extent possible, in combination with and/or in the context of other particular aspects and embodiments of the invention, and in the invention generally. The term “comprises” and grammatical equivalents thereof are used herein to mean that other components, ingredients, steps, etc. are optionally present. For example, an article “comprising” (or “which comprises”) components A, B, and C can consist of (i.e., contain only) components A, B, and C, or can contain not only components A, B, and C but also one or more other components. Where reference is made herein to a method comprising two or more defined steps, the defined steps can be carried out in any order or simultaneously (except where the context excludes that possibility), and the method can include one or more other steps which are carried out before any of the defined steps, between two of the defined steps, or after all the defined steps (except where the context excludes that possibility).

The term “at least” followed by a number is used herein to denote the start of a range beginning with that number (which may be a range having an upper limit or no upper limit, depending on the variable being defined). For example “at least 1” means 1 or more than 1. The term “at most” followed by a number is used herein to denote the end of a range ending with that number (which may be a range having 1 or 0 as its lower limit, or a range having no lower limit, depending upon the variable being defined). For example, “at most 4” means 4 or less than 4, and “at most 40%” means 40% or less than 40%. When, in this specification, a range is given as “(a first number) to (a second number)” or “(a first number)-(a second number),” this means a range whose lower limit is the first number and whose upper limit is the second number. For example, 25 to 100 mm means a range whose lower limit is 25 mm, and whose upper limit is 100 mm. The embodiments set forth the below represent the necessary information to enable those skilled in the art to practice the invention and illustrate the best mode of practicing the invention. In addition, the invention does not require that all the advantageous features and all the advantages need to be incorporated into every embodiment of the invention.

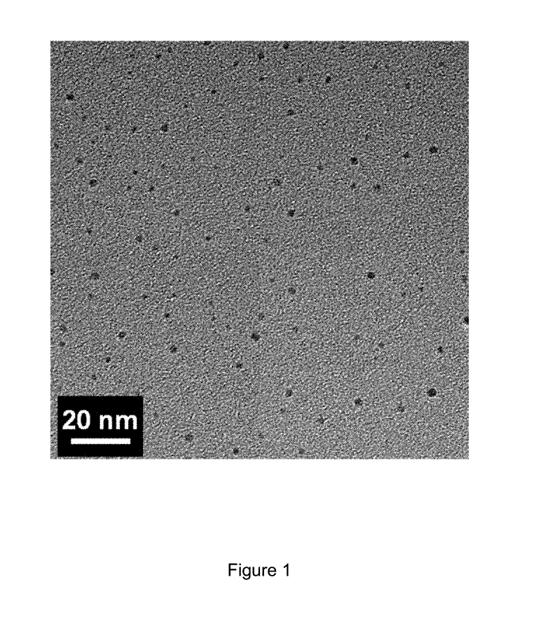

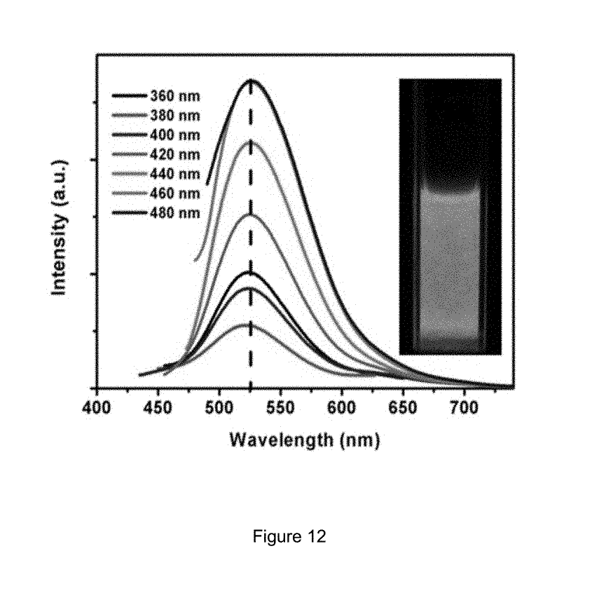

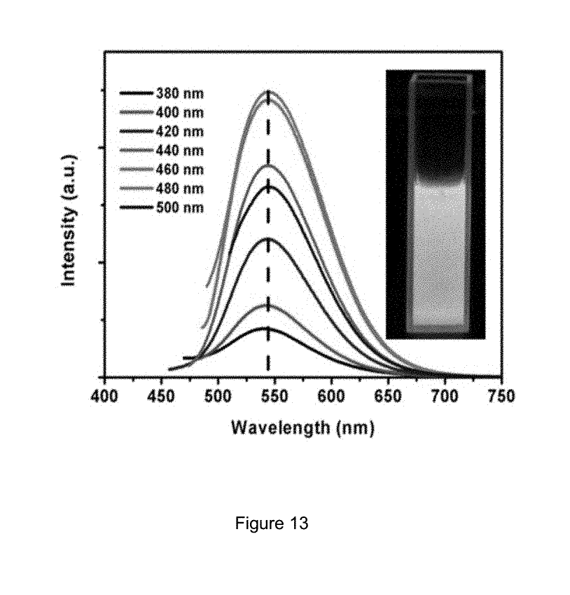

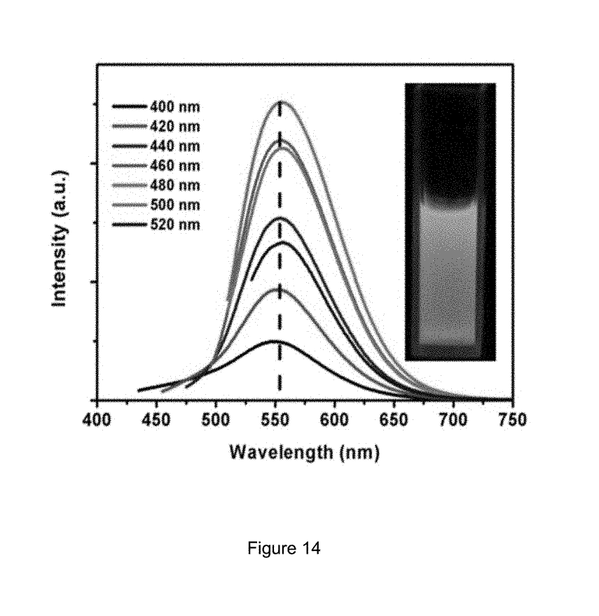

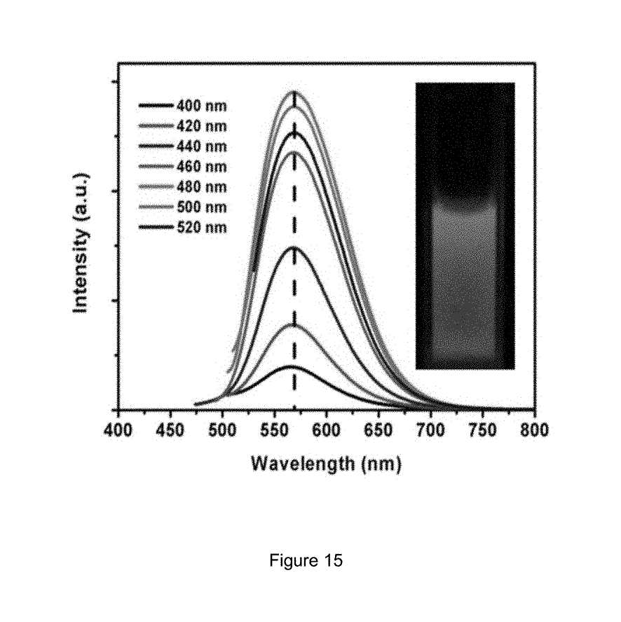

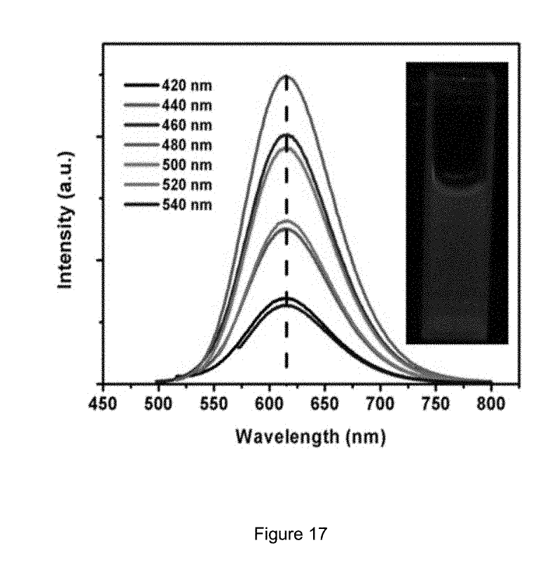

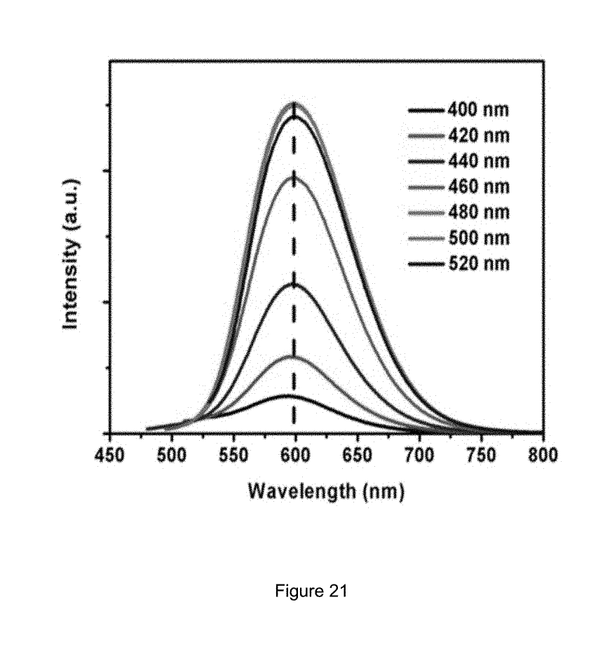

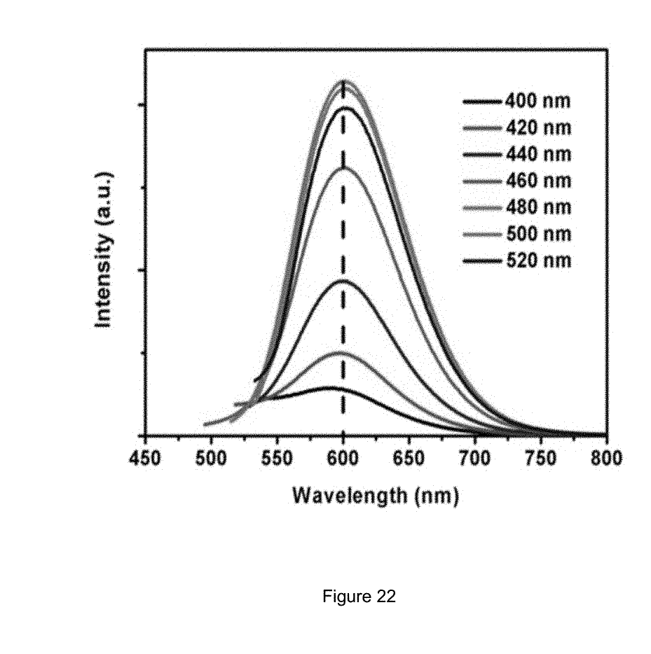

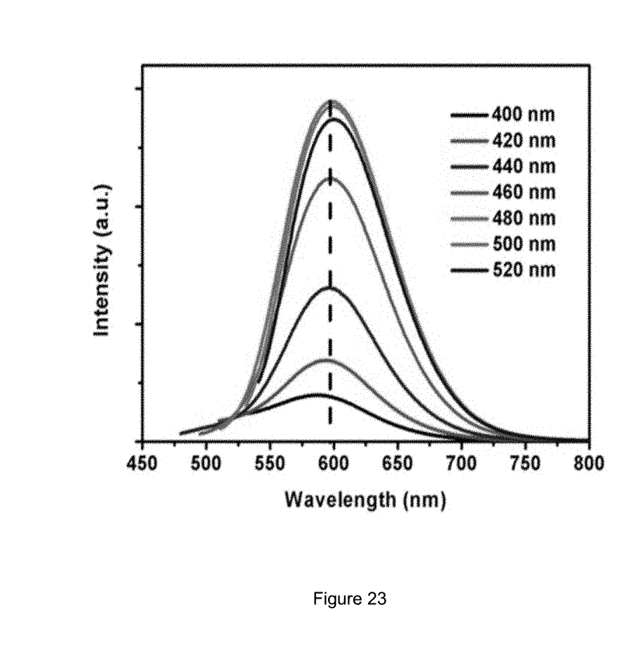

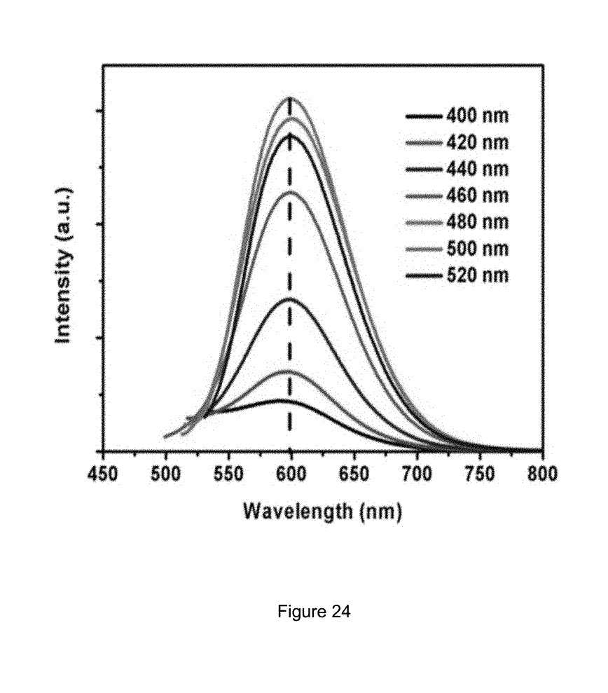

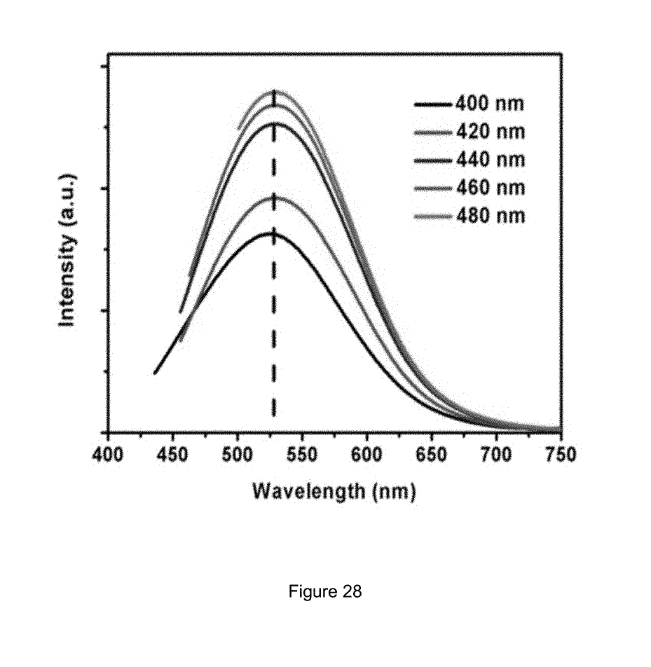

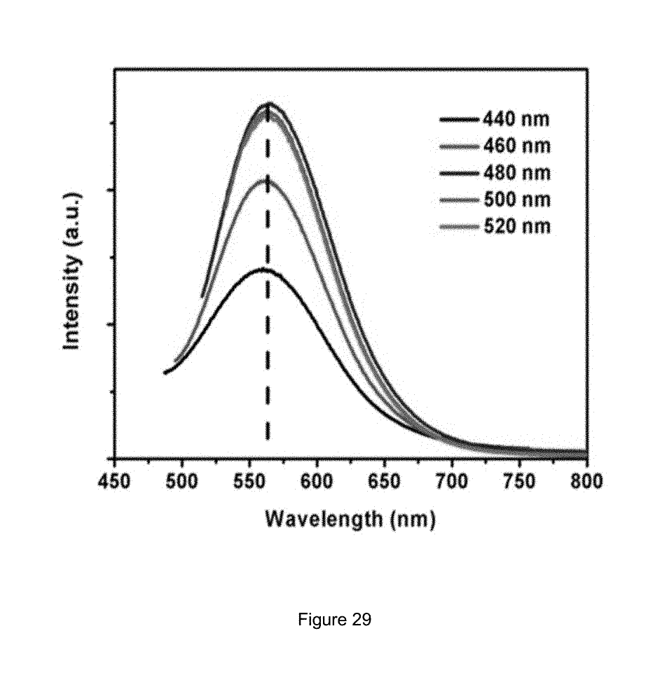

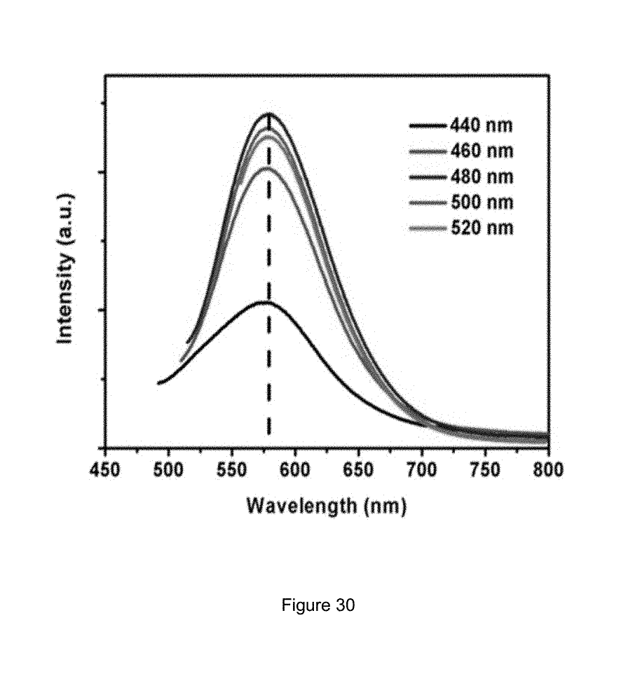

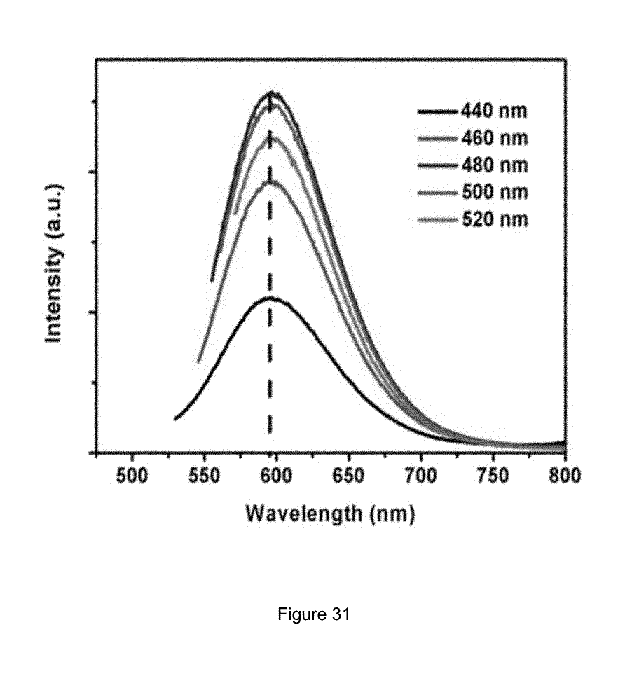

Turning now to FIGS. 1-34, a brief description concerning the various components of exemplary embodiments of the present invention will now be briefly discussed. In a three-neck, round bottomed flask with reflux condensation system, diphenyl ether (15 mL) was heated to 250° C. p-Phenylenediamine (0.20 g, 1.8 mmol) was dispersed in diphenyl ether (1 mL) and heated to 80° C. to completely dissolve. Then the p-phenylenediamine solution was quickly injected into the flask. The mixture was kept on 250° C. for 8 h and then cooled down to room temperature. The mixture was poured into hexane (100 mL) to precipitate. Then the whole mixture was centrifuged at 4000 rpm for 20 min. After repeating the precipitation and centrifugation process for three times, 0.164 g of black powder was obtained. The yield was 82% for this case, but the yield could be 95% with careful purification.

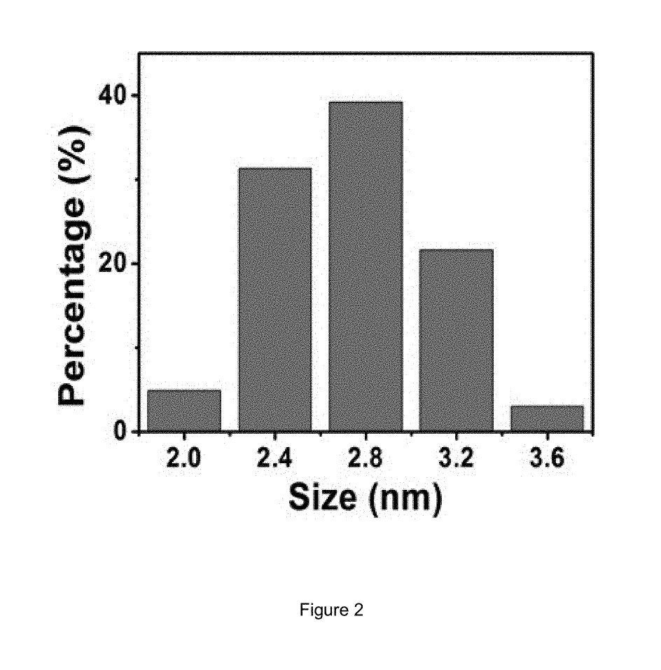

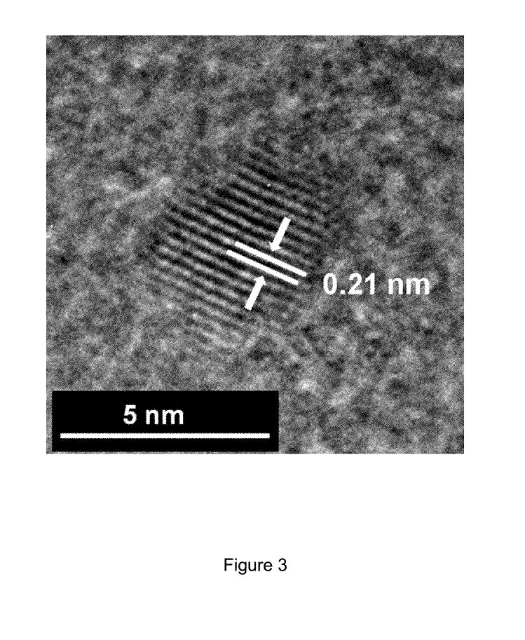

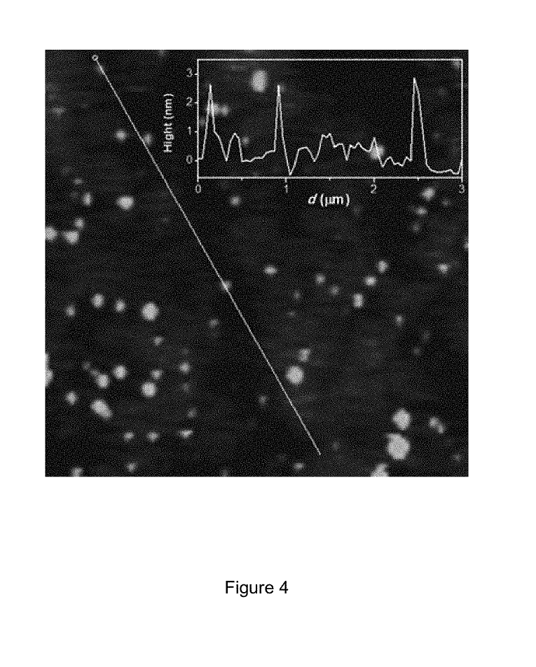

The morphology of the CDs was characterized by transmission electron microscopy (TEM) and atomic force microscopy (AFM). As shown in FIG. 1 and FIG. 2, the CDs have diameters in a range of 2.0 to 3.4 nm and the average diameter is 2.6 nm. The high-resolution TEM (HRTEM) image shows that the CDs have clear crystalline lattice fringes (FIG. 3). The 0.21 nm spacing is attributed to the (100) in-plane lattice of graphene. The AFM image of CDs (FIG. 4) exhibits similar results to the TEM characterization; the CD's topographic height is about 2.7 nm, indicating that the CDs are nearly spherical in shape.

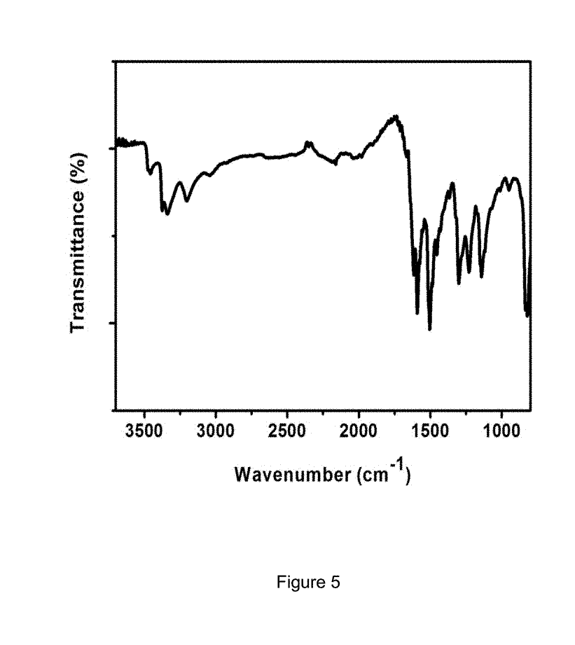

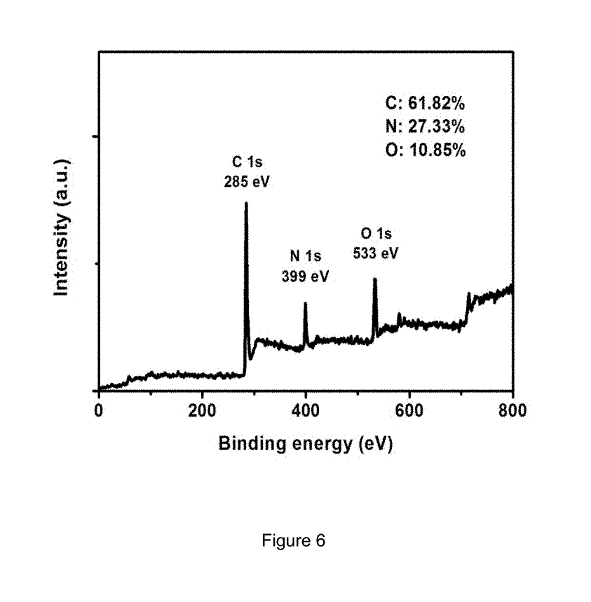

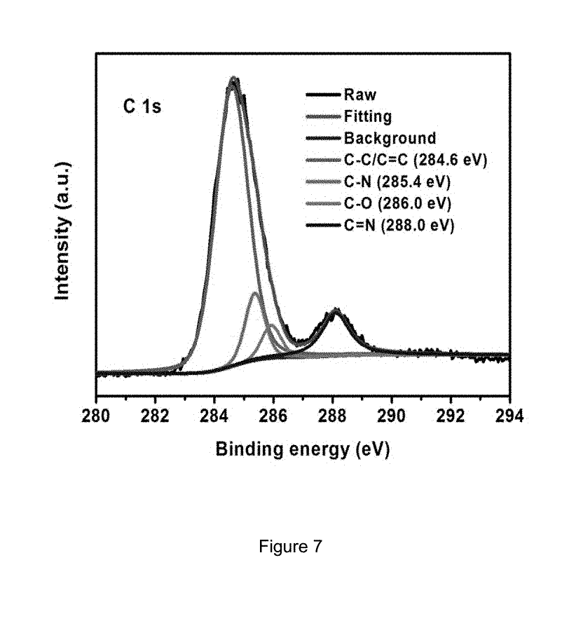

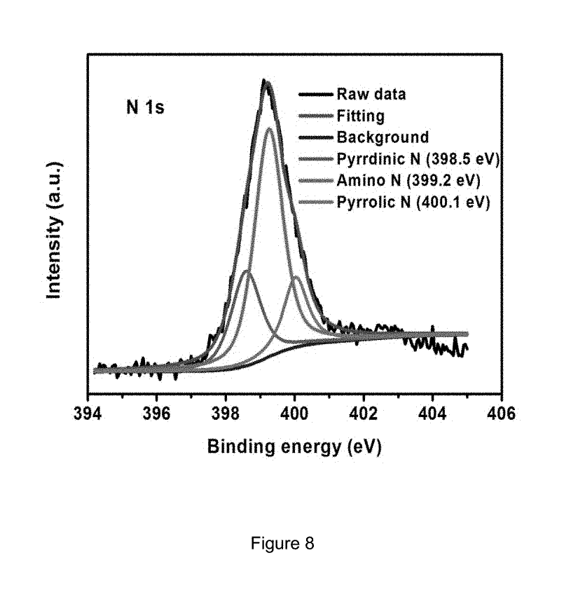

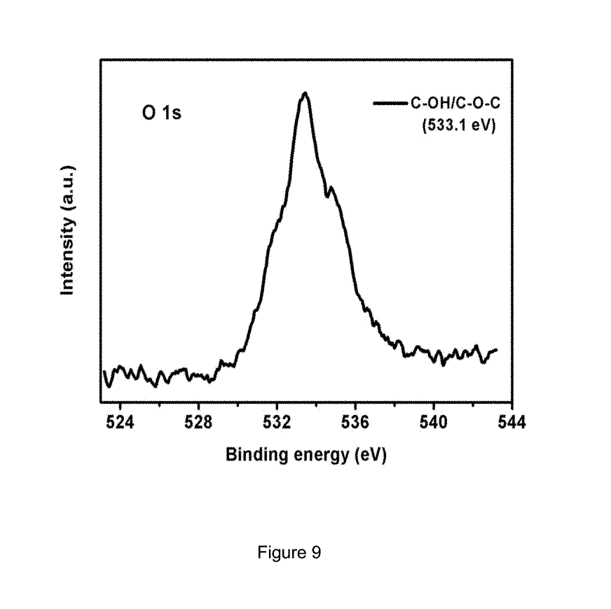

The surface functional groups and chemical composition of CDs were investigated by the Fourier transform infrared (FTIR) and X-ray photoelectron spectroscopy (XPS). The FTIR spectrum is shown in FIG. 5. Many bonds are seen in the CDs, such as —OH (3468 cm⁻¹), N—H (3383-3193 cm⁻¹), C—H (3031 cm⁻¹), C═N (1638 cm⁻¹), C═C (1597 cm⁻¹), C—N (1493 and 1304 cm⁻¹), and C—O (1140 cm⁻¹). It reveals that the CDs are composed of aromatic structures and possessed abundant —NH₂ on their surface. XPS was used to further explore the CD surface. The spectrum presented in FIG. 6 shows three typical peaks: C 1s (285 eV), N 1s (399 eV), and O 1s (533 eV), indicating that the CDs are consisted of C, N and O elements. In this embodiment, the atomic percentages of C, N and O were 61.82%, 27.33%, and 10.85%, respectively, and the atomic ratio of C, N and O elements was therefore calculated as 5.7:2.5:1. In the high-resolution XPS spectrum of C 1s (FIG. 7), there are four peaks for different states of carbon: C—C/C═C (284.6 eV), C—N (285.4 eV), C—O (286.0 eV), and C═N (288.0 eV). The N 1s high-resolution XPS spectrum (FIG. 8) can be analyzed as three peaks at 398.6, 399.3 and 400.2 eV, representing pyridinic, amino and pyrrolic N. It indicates that the CDs contain many nitrogenous fused-ring structures. The O 1s spectrum (FIG. 9) only shows one peak at 533.1 eV which can be attributed to the C—O bond.

The CDs exhibited excellent solubility in many organic solvents, such as carbon tetrachloride (CCl₄), toluene, chloroform (CHCl₃), acetone, N,N-dimethylformamide (DMF), and methanol (CH₃OH). However, the CDs have relatively poor solubility in water. The clear CD water solution could be obtained with ultrasound, but a little precipitate appeared after 24 hours at room temperature.

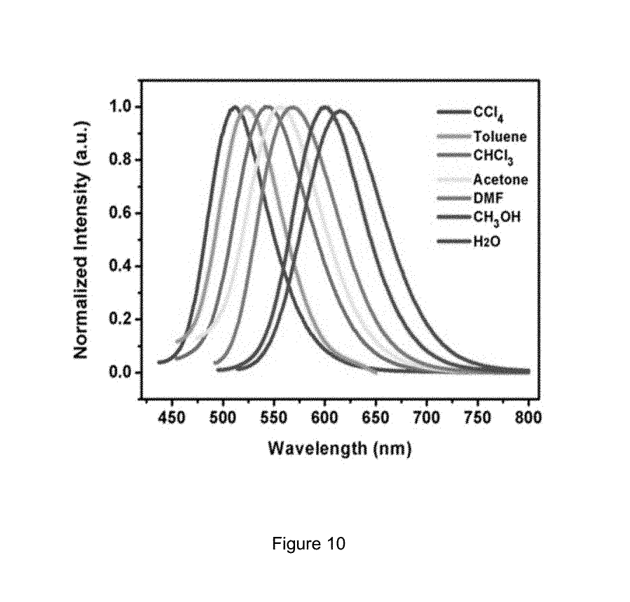

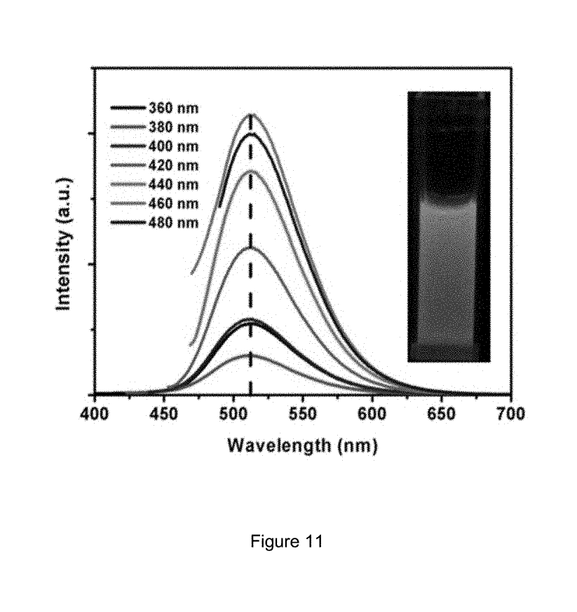

As shown in FIG. 10, the CDs in different solvents exhibited different photoluminescence peaks under a single excitation wavelength. The emission peaks were observed at 511, 525, 545, 554, 568, 602 and 615 nm in CCl₄, toluene, CHCl₃, acetone, DMF, CH₃OH and H₂O, respectively, showing as dark green, green, yellow-green, yellow, dark yellow, orange-red and red emission colors (see the insets in FIG. 11 to FIG. 17). In general, the emission peaks shifted to red as the solvent polarity increased. In contrast to the current technology carbon dots with solvent-dependent properties, the disclosed synthesized CDs exhibited a much broader color tunable range of 511-615 nm. Furthermore, it can be clearly seen from FIG. 11-FIG. 17 that the fluorescence emission bands of the disclosed CDs in any solvent do not shift with different excitation wavelengths. This excitation wavelength independence is distinctive in these disclosed CDs. This property gives easy handling and design of multicolor applications, and the existing use of traditional quantum dots (such as Cd or Pb chalcogenides) can be easily switched to these inventive CDs to reduce the synthesis complexity and production cost, and to eliminate the biological and ecological toxicity inherent in the quantum dots using heavy metals of Cd, Pb, etc.

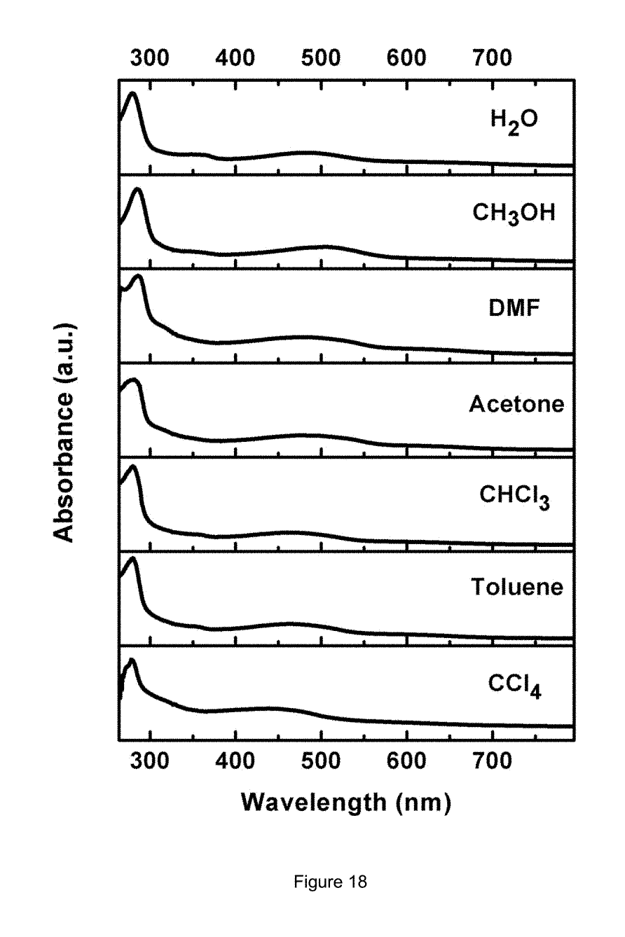

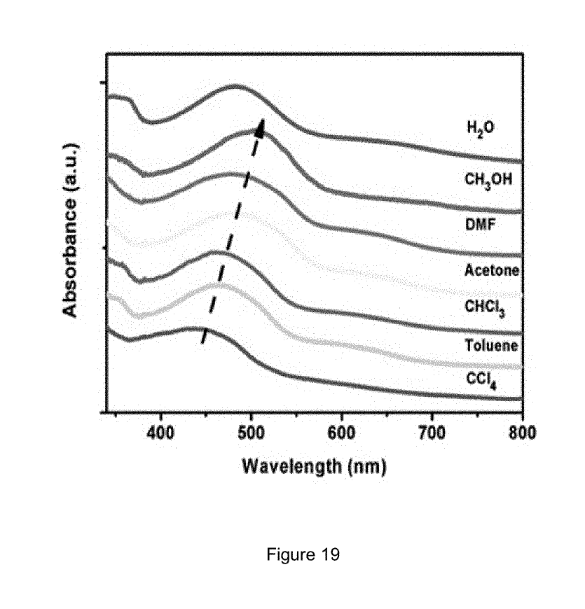

The UV absorption spectra were measured for the CDs in different solvents (FIG. 18). In the high-energy region (200-350 nm) of all the spectra, a same peak was observed at 280 nm, corresponding to the π-π* transitions of C═C and C═N bonds. The fluorescence visible emission of CDs in different solvents clearly originated from the absorption in the lower-energy region (350-800 nm). In the lower-energy region (amplified as shown in FIG. 19), the spectra exhibit distinct absorption bands at 448, 461, 464, 471, 478, 500, and 488 nm, indicating that the CDs possess different energy gaps in different solvents. As the solvent polarity increases, the absorption wavelength exhibits red shift except in water. The inconsistency in water could be resulted from the weak solubility and therefore the aggregation of CDs.

The QYs of the CDs in different solvents were measured and are shown in Table 1. It can be seen that the CDs have good QYs in all the seven solvents. The CDs exhibited the highest QY of 34.5% in CHCl₃ for the green emission color but a low QY (9.2%) in water (red); the latter is attributed to the poor water solubility of the CDs. In water, the CDs are kind of aggregated and the fluorescence is thus greatly quenched because of the excessive resonance energy transfer or π-π interactions.

TABLE 1
The photoluminescent properties of CDs in different solvents

| Solvent | CCl₄ | Toluene | CHCl₃ | Acetone | DMF | CH₃OH | H₂O |
|---|---|---|---|---|---|---|---|
| Emission | 511 | 525 | 545 | 554 | 568 | 602 | 615 |
| peak (nm) | | | | | | | |
| QY (%) | 11.8 | 18.4 | 34.5 | 16.9 | 13.3 | 24.8 | 9.2 |

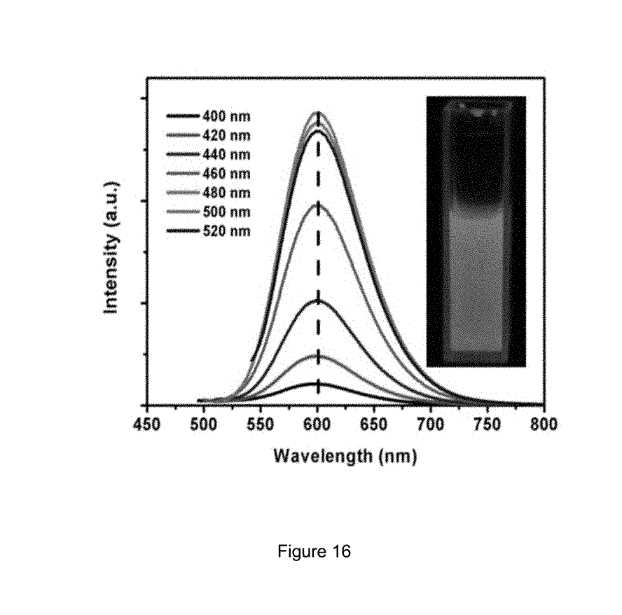

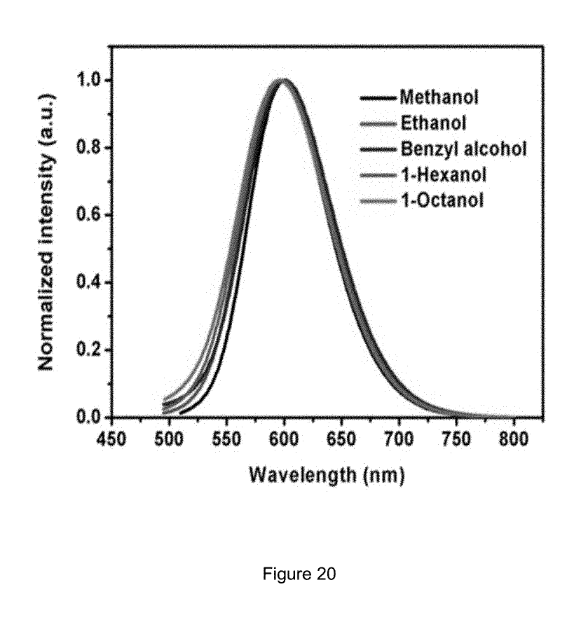

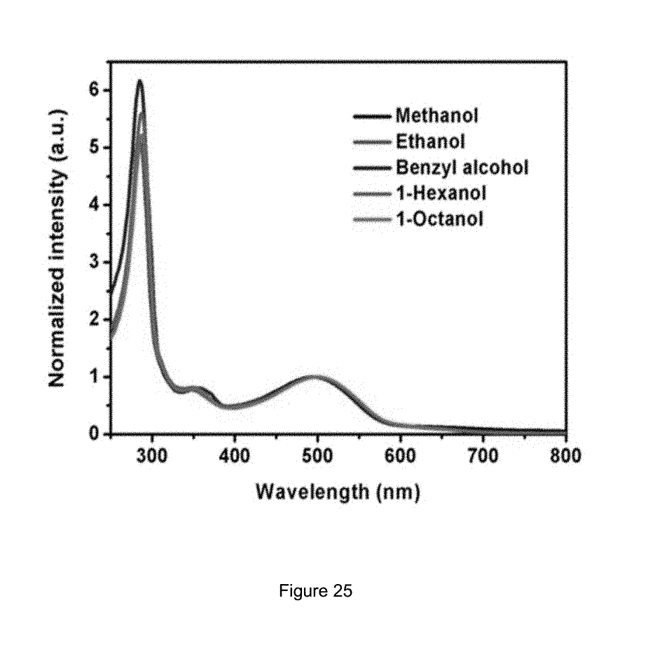

For the organic dyes with solvatochromism effect, they usually exhibit very weak fluorescence in CH₃OH because of the high solvent polarity. However, the disclosed CDs exhibited strong orange-red emission in CH₃OH (QY 24.8%) which was higher than those in acetone and DMF. The CDs were dissolved in methanol, ethanol, benzyl alcohol, 1-hexanol and 1-octanol with successively decreased polarities (Table 2). The CDs exhibited excellent solubility in all these alcohol solvents. But the CDs in these alcohol solvents showed almost the same fluorescence spectra (FIG. 20). All the emission peaks were very close with slight variations from 598 to 602 nm (Table 2). The fluorescence emission bands of CDs in any of the alcohol solvents also did not shift with different excitation wavelengths, i.e. excitation wavelength independent (FIG. 16 and FIG. 21 to FIG. 24). Besides, the absorption spectra showed very similar profiles for all the alcohol solvents (FIG. 25). The absorption peaks in low-energy region merely changed (from 496 to 500 nm). The polarities of these five alcohol solvents were very different. However, the CDs in these solvents exhibited almost the same absorption and photoluminescence spectra. According to these results, it can be inferred that the absorption and photoluminescence of the CDs in alcohol solvents are dominated by the —OH groups rather than the solvent polarity effect. In alcohol solvents, the nitrogen atoms on the surface of the CDs can form strong hydrogen bonds to alcohol molecules, which lead to the stabilization of the excited state. And this effect leads to the very similar strong orange-red emission in different alcohol solvents. Besides, the QYs of the CDs in the alcohol solvents were also measured to be a 30% level from 24.8% to 34.7% (Table 2). As the alcohol solvent polarity decreases, the QY of the CDs increases which is similar to organic dyes' behavior. The QY is 34.7% in 1-octanol, which is among the highest values in the reported orange-red emission CDs. Based on this unique property, these CDs are anticipated to be a good fluorescent probe for the detection of compounds with hydroxyl groups, and such use is considered part of the disclosed invention.

TABLE 2
The QYs of CDs in five alcohol solvents

| Solvent | Methanol | Ethanol | Benzyl alcohol | 1-Hexanol | 1-Octanol |
|---|---|---|---|---|---|
| Emission | 602 | 598 | 601 | 598 | 599 |
| peak (nm) | | | | | |
| QY (%) | 24.8 | 27.7 | 28.5 | 33.5 | 34.7 |

In the present invention, the CD's photoluminescence is generally attributed to the surface states. According to the FTIR and XPS data, the CDs have a high nitrogen composition (27.33%) and abundant nitro-containing groups on the surface of CDs. For many organic dyes containing nitrogen fused-ring structures, their photoluminescence have obvious solvatochromism effect. Therefore, the luminescent centers on these CD surfaces are mainly composed of conjugated carbon atoms and bonded nitrogen atoms. These carbon and nitrogen atoms form unique nitrogen fused-ring structures. Apparently like organic dyes, the stable excited states of such structures on the CD surface are strongly influenced by the dipole moment of the solvents. As the solvent polarity increases, the dipole moment effect to the CD surface from the solvent enhances. Then it reduces the energy gap and results in the red shifts of fluorescence emission wavelength.

Based on the excitation wavelength independent multicolor photoluminescence, solid CD emission materials can be made with polymers and the CD/polymer composites also emit different colors with different polymers. Five polymers (any molecular weight) were chosen to make CD/polymer composites: polystyrene (PS), poly(methyl methacrylate) (PMMA), poly(vinyl pyrrolidone) (PVP), poly(ethylene glycol) (PEG), and poly(vinyl alcohol) (PVA). They were chosen based on the groups which were similar to the above-mentioned solvents. One example is to prepare solid CD/polymer films. For each CD/polymer film preparation (CD/PS, CD/PMMA, CD/PVP, and CD/PEG), a selected polymer of 0.20 g was mixed with 1 mL CD solution (1.0 mg in dichloromethane) and treated by ultrasound to a complete dissolution. Then the obtained mixture was transferred into a clean glass vial and dried overnight under ambient circumstances to get the composite film. For CD/PVA film preparation, 0.50 g PVA was mixed with 1 mL CD solution (1.0 mg in water) and heated to 80° C. to be completely dissolved. The obtained mixture was transferred into a clean glass vial and dried overnight under ambient circumstances to get the composite film for red emission. Vacuum and heating can help to accelerate the drying process.

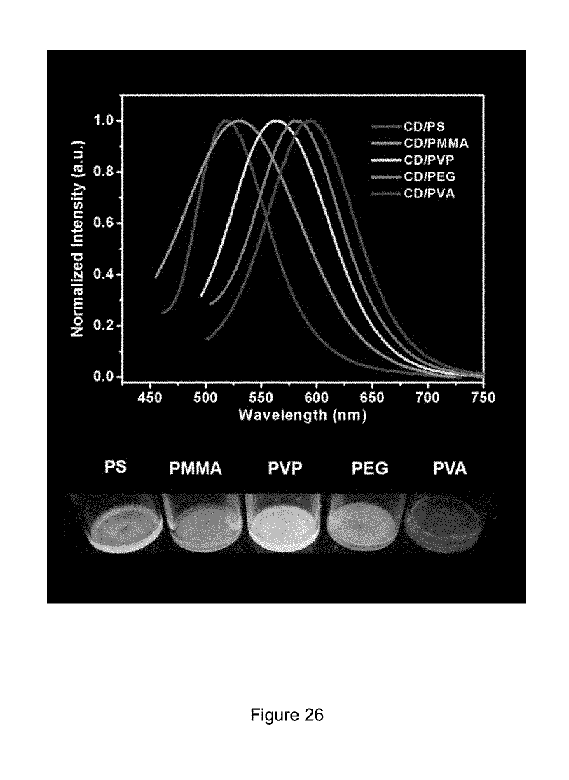

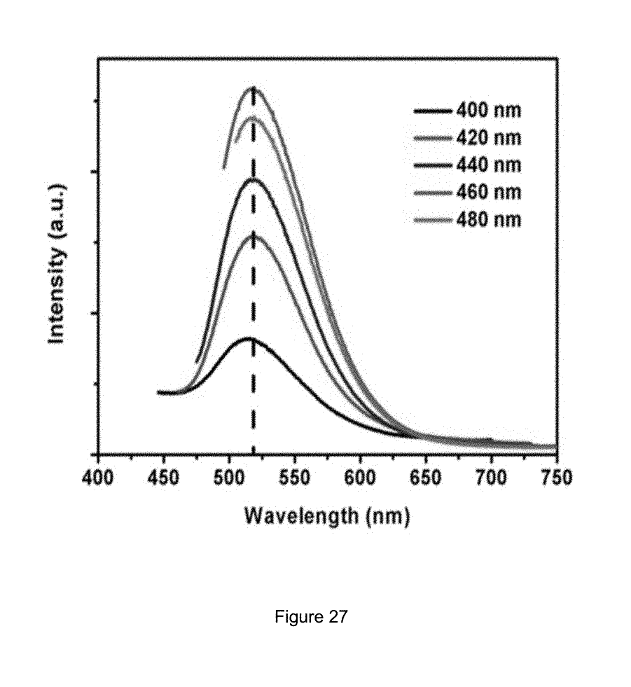

As shown in FIG. 26 (top), the emission peaks of the CD/polymer films were 518, 531, 564, 580, and 594 nm with PS, PMMA, PVP, PEG, and PVA, respectively. All the five CD/polymer films exhibited strong photoluminescence lights from dark green to red (FIG. 26 bottom). This means that the same CDs emit different colors when mixed in different polymers under a single excitation wavelength. For each composite, the emission peak did not change when excited by lights of different excitation wavelengths, i.e., excitation wavelength independent emissions as happened in solutions (FIG. 27 to FIG. 31). The mechanism of the color-tuning in different polymers is similar to that occurred in different solvents. The polymers around the CD particles exert the same interaction with the surface of the CDs and therefore change their surface states. Based on the large number of commercially available polymers and new polymers which are constantly designed and synthesized in the labs, CDs have great potentials to make various solid phosphors for many sorts of applications, such as LEDs for color display (for example, use one color of CD phosphor to emit a single color light excited by a blue or UV LED chip) and white lighting (for example, using a blue LED chip to excite a green and a red CD phosphors at the same time to generate a white light), medical imaging and biolabeling, optical tracking, emission or color based sensors and probes, anti-fake ink or labels.

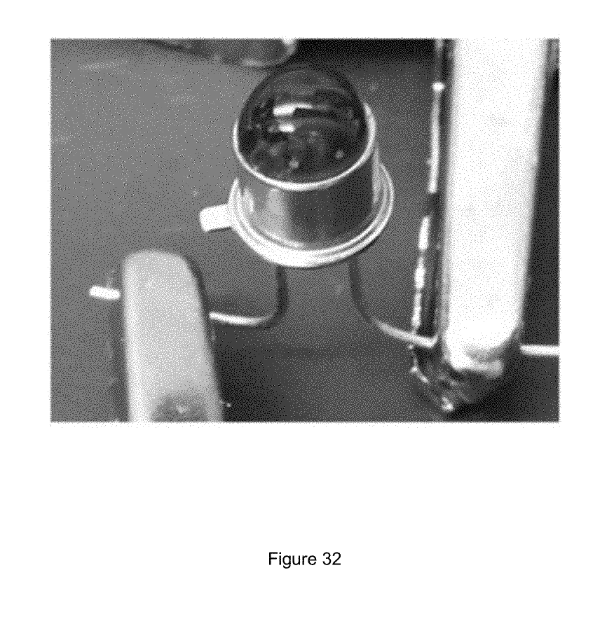

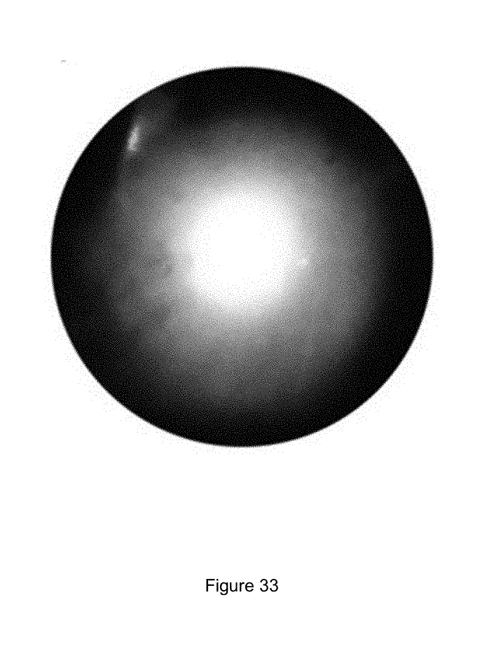

FIG. 32 shows a final formation of solid CD/polymer composite coated on a 370-nm UV LED chip (CD-LED). When use CD/PMMA composite on the UV LED chip, it emits bright green emission (FIG. 33). When use CD/PVA composite on the UV LED chip, it emits bright red emission (FIG. 33).

In further embodiments an additional or alternative solvents may be used for the CDs preparation, including ones without active functional groups, such as diphenyl ether, biphenyl, terphenyl, high boiling point alkanes (e.g., octadecane, docosane), etc. The synthesis temperature can be around 200 to 300° C., or potentially even higher. Further starting materials can be o-phenylenediamine, m-phenylenediamine, 2,5-dichloro-p-phenylenediamine, or some other molecules with similar structures.

### EXEMPLARY EMBODIMENTS

Synthesis of CDs with multiple colors from 2,5-dichloro-p-phenylenediamine. 2,5-Dichloro-p-phenylenediamine (0.20 g, 1.8 mmol) was mixed in diphenyl ether (2 ml) and heated to 80° C. for a complete dissolution. Then the solution was quickly injected into 250° C. diphenyl ether (15 ml) in a three-neck flask equipped with a reflux condenser. The reaction was maintained at 250° C. for 6 h and then cooled down to room temperature. The mixture was poured into hexane (100 ml) and was centrifuged at 7000 rpm for 20 min to precipitate out the product. After repeating the precipitation and centrifugation for three times, the pure product as black powder was obtained with yields usually higher than 80%.

Green emitting CD-LED device. PMMA of 0.20 g was mixed with 1 mL CD solution (1.0 mg in dichloromethane) and treated by ultrasound to a complete dissolution. Then the obtained mixture was transferred into a clean glass vial and dried overnight under ambient circumstances to get a composite film (FIG. 26 bottom). Another way was to pour the CD and PMMA mixed solution into a semi-sphere mold and let it dry overnight at room temperature (replenish if the volume becomes significantly smaller) to get a semi-sphere shaped composite solid (FIG. 32 top part). Cut the films to fit the size of a UV or blue ELD chip, or cover the chip with the semi-sphere shaped composite solid. Turn on the chip (provide power from an electrical power source, such as an cord or battery) and green emission can be seen from the semi-sphere shaped composite solid (FIG. 33).

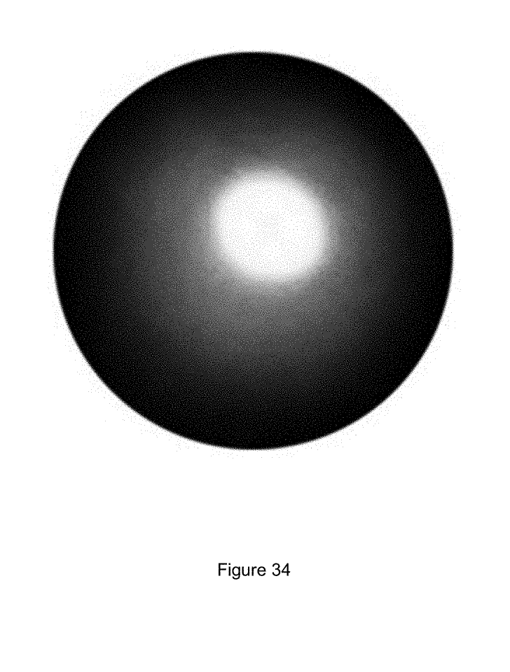

Red emitting CD-LED device. 0.50 g PVA was mixed with 1 mL CD solution (1.0 mg in water) and heated to 80° C. to be completely dissolved. The obtained mixture was transferred into a clean glass vial and dried overnight under ambient circumstances to get the composite film (FIG. 26 bottom). Another way was to pour the CD and PVA mixed solution into a semi-sphere mold and let it dry overnight at room temperature (replenish if the volume becomes significantly smaller) to get a semi-sphere shaped composite solid (FIG. 32 top part). Cut the films to fit the size of a UV or blue ELD chip, or cover the chip with semi-sphere composite solid. Turn on the chip and red emission can be seen from the semi-sphere shaped composite solid (FIG. 34).

The invention illustratively disclosed herein suitably may explicitly be practiced in the absence of any element which is not specifically disclosed herein. While various embodiments of the present invention have been described in detail, it is apparent that various modifications and alterations of those embodiments will occur to and be readily apparent those skilled in the art. However, it is to be expressly understood that such modifications and alterations are within the scope and spirit of the present invention, as set forth in the appended claims. Further, the invention(s) described herein is capable of other embodiments and of being practiced or of being carried out in various other related ways. In addition, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items while only the terms “consisting of” and “consisting only of” are to be construed in the limitative sense.

Wherefore I/We claim:

1. An electroluminescent light emitting diode (LED) device comprising:
a hole transport layer;
an electron transport layer;
an active emissive layer between the hole transport layer and the electron transport layer; and
the active emissive layer being formed with carbon dots.

2. The electroluminescent LED device of claim 1, wherein the carbon dots are formed of organic carbon-containing materials.

3. The electroluminescent LED device of claim 1, wherein the carbon dots are formed of inorganic carbon-containing materials.

4. The electroluminescent LED device of claim 1, wherein the carbon dots are between 0.5 and 20 nm in width.

5. The electroluminescent LED device of claim 1 further comprising a transparent conducting film anode,

6. The electroluminescent LED device of claim 5, wherein the transparent conducting film anode includes one of indium tin oxide (ITO), fluorine doped tin oxide (FTO), carbon nanotube networks, and graphene.

7. The electroluminescent LED device of claim 1 further comprising a hole injection layer (HIL).

8. The electroluminescent LED device of claim 7, wherein the hole injection layer includes poly(ethylenedioxythiophene):polystyrene sulphonate (PEDOT:PSS) and the hole injection layer has a thickness of between 10 and 100 nm.

9. The electroluminescent LED device of claim 1, wherein the hole transport layer (HTL) includes one of poly(N,N′-bis(4-butylphenyl)-N,N′-bis(phenyl) benzidine) (poly-TPD) and poly(N-vinylcarbazole) (PVK).

10. The electroluminescent LED device of claim 9, wherein the hole transport layer has a thickness of between 10 and 100 nm.

11. The electroluminescent LED device of claim 1, wherein the carbon-dot active emissive layer has a thickness of between 10 and 100 nm.

12. The electroluminescent LED device of claim 1, wherein the electron transport layer includes 1,3,5-tris(N-phenylbenzimidazol-2-yl) benzene (TPBI) and is a thickness of between 2 to 50 nm thick.

13. The electroluminescent LED device of claim 12 further comprising a LiF/Al bilayer cathode, where the LiF layer has a thickness of between 1 and 20 nm and the Al layer has a thickness of between 10 and 300 nm.

14. The electroluminescent LED device of claim 1, wherein the electron transport layer includes ZnO nanoparticles, and the electron transport layer has a thickness of between 5 and 100 nm thick.

15. The electroluminescent LED device of claim 14 further comprising an Al cathode having a thickness of 10 between 300 nm.

16. The electroluminescent LED device of claim 1 further comprising a hole injection layer sandwiched between a transparent conducting film anode and the hole transport layer, wherein the electron transport layer is sandwiched between the carbon dot active emissive layer and a cathode.

17. A method of producing light comprising:
supplying a current of electricity to an electroluminescent light emitting diode (LED);
wherein the electroluminescent LED device comprises a hole transport layer, an electron transport layer, an active layer between the hole transport layer and the electron transport layer, and carbon dots form the active layer.

18. The method of claim 17 further comprising the step of varying an injection current density supplied to the electroluminescent LED device.

19. The method of claim 17 further comprising the step of changing a color emission by varying an injection current density supplied to the electroluminescent LED device.

20. A method of forming an electroluminescent light emitting diode (LED) device comprising the steps of:
treating a transparent conducting film with UV-ozone;
depositing a hole injection layer on the treated transparent conducting film;
annealing the hole injection layer in an oven at 120° C. for 10 min in air;
spin casting a hole transport layer on the hole injection layer;
curing the hole transport layer at 150° C. for 30 min;
spin coating a carbon dot (CD)-active emissive layer over a surface of the hole transport layer;
baking the CD active emissive layer at 80° C. for 30 min;
thermally depositing an electron transport layer over the CD-active emissive layer; and
one of
thermally evaporating a LiF/AI bilayer cathode through a shadow mask and
spin coating a ZnO nanoparticle electron transport layer over the CD-emissive layer, and the thermally evaporating an Al cathode through a shadow mask.
